(19) United States
(12) Patent Application Publication
(10) Pub. No.: US 2026/0070792 A1
(43) Pub. Date: Mar. 12, 2026

(54) METHOD FOR PRODUCING HALOTRISILANE AND METHOD FOR MANUFACTURING SEMICONDUCTOR DEVICES USING THE SAME

(71) Applicant: Samsung Electronics Co., Ltd., Suwon-si (KR)

(72) Inventors: Hyeonggeun LIM, Suwon-si (KR); Sheby Mary GEORGE, Cheongju-si (KR); Woori BAE, Cheongju-si (KR); Jieun YUN, Suwon-si (KR); Byungkeun HWANG, Suwon-si (KR); Sunhye HWANG, Suwon-si (KR); Seongho HAN, Cheongju-si (KR)

(73) Assignees: Samsung Electronics Co., Ltd., Suwon-si (KR); Wonik Materials, Cheongju-si (KR)

(21) Appl. No.: 19/197,369

(22) Filed: May 2, 2025

(30) Foreign Application Priority Data
Sep. 6, 2024 (KR) 10-2024-0121784

(51) Int. Cl. C01B 33/107; H01L 21/02

(52) U.S. Cl. CPC C01B 33/10773; H10P 14/24; H10P 14/3411

(57) ABSTRACT

A halotrisilane preparation method may include providing a reactant that contains halotrisilane including M halogen atoms (where, M may be a natural number from 2 to 8), reducing the halotrisilane in the reactant by using a mixed reducing agent that includes a first reducing agent represented by Formula 1-1 and a second reducing agent represented by Formula 2-1, and obtaining a product that contains the reduced halotrisilane that includes N halogen atoms, where N may be a natural number from 1 to 7 and where N<M.

$${( {R}_{A} )}_{a} - Al - {H}_{b} \qquad [ Formula 1 - 1 ]$$

In Formula 1-1 above, R_{A} may represent an alkyl group, a and b each may be either 1 or 2, and a+b=3.

$${( {R}_{S} )}_{p} - Sn - {H}_{q} \qquad [ Formula 2 - 1 ]$$

In Formula 2-1 above, R_{S} may represent an alkyl group or an aryl group, p and q each independently may be a natural number from 1 to 3, and p+q=4.

### CROSS-REFERENCE TO RELATED APPLICATION

This application is based on and claims priority under 35 U.S.C. § 119 to Korean Patent Application No. 10-2024-0121784, filed on Sep. 6, 2024 in the Korean Intellectual Property Office, the disclosure of which is incorporated by reference herein in its entirety.

### BACKGROUND

Inventive concepts relate to a halotrisilane preparation method and/or a method of manufacturing a semiconductor device by using the halotrisilane preparation method, and more particularly, to a halotrisilane preparation method using a reducing agent and/or a method of manufacturing a semiconductor device by using the halotrisilane preparation method.

Silane compounds are used in the electronics field and particularly used as silicon precursors for forming silicon-containing layers on substrates. Among these silane compounds, halotrisilane is known as an excellent silicon precursor during low-temperature deposition of silicon-containing films.

In this regard, disilane (Si₂H₆) has activation energy ranging from about 1.84 eV to about 1.88 eV, and trisilane (Si₃H₆) has activation energy ranging from about 1.74 eV to about 1.78 eV. Because halotrisilane, which has a relatively higher order than halodisilane, exhibits relatively low activation energy (e.g., activation energy during epitaxial process) in the same manner that a high-order silane has relatively low activation energy (e.g., activation energy during epitaxial process), halotrisilane may be more advantageous for the deposition of silicon-containing films at low temperatures compared to halodisilane. Therefore, there may be a need for a halotrisilane preparation method that is suitable for mass production.

### SUMMARY

Inventive concepts provide a halotrisilane preparation method that is relatively advantageous for deposition of silicon-containing films at low temperatures.

Inventive concepts also provide a method of manufacturing a semiconductor device with improved productivity by using the halotrisilane preparation method that is relatively advantageous for deposition of silicon-containing films at low temperatures.

Aspects of inventive concepts are not limited to the above description, and other aspects may be clearly understood by one of ordinary skill in the art from the descriptions provided hereinafter.

According to an example embodiment of inventive concepts, a halotrisilane preparation method may include providing a reactant that contains halotrisilane comprising M halogen atoms, where M may be a natural number from 2 to 8; reducing the halotrisilane in the reactant using a mixed reducing agent to provide a reduced halotrisilane, the mixed reducing agent including a first reducing agent represented by Formula 1-1 and a second reducing agent represented by Formula 2-1; and obtaining a product including the reduced halotrisilane, the reduced halotrisilane including N halogen atoms, where N may be a natural number from 1 to 7 and where N may be less than M.

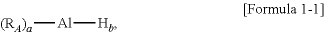

In Formula 1-1 above, R_{A} may represent an alkyl group, a and b each may be either 1 or 2, and a+b may equal 3.

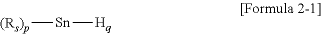

In Formula 2-1 above, R_{S} may represent an alkyl group or an aryl group, p and q each independently may be a natural number from 1 to 3, and p+q may be equal to 4.

According to an example embodiment of inventive concepts, a halotrisilane preparation method may include providing a reactant that contains halotrisilane comprising M halogen atoms, where M may be a natural number from 2 to 8; cooling the reactant to a first temperature that may be higher than a freezing point of the reactant and lower than room temperature, the cooling the reactant providing a cooled reactant; forming a mixture by adding a mixed reducing agent to the cooled reactant, the mixed reducing agent including an aluminum-based first reducing agent and a tin-based second reducing agent; agitating the mixture at a second temperature, the second temperature being higher than the first temperature; and separating, from the mixture, a product including halotrisilane comprising N halogen atoms, where N may be a natural number from 1 to 7 and where N may be less than M.

According to an example embodiment of inventive concepts, a method of manufacturing a semiconductor device may include providing a substrate; providing a silicon precursor on the substrate; and forming a silicon-containing layer using the silicon precursor on the substrate. The silicon precursor may include halotrisilane with at least one halogen atom. The providing the silicon precursor may include providing octahalotrisilane and reducing the octahalotrisilane using a mixed reducing agent. The mixed reducing agent may include an aluminum-based first reducing agent and a tin-based second reducing agent.

### BRIEF DESCRIPTION OF THE DRAWINGS

Embodiments will be more clearly understood from the following detailed description taken in conjunction with the accompanying drawings in which:

FIG. 1 is a diagram to explain a halotrisilane preparation method according to some embodiments;

FIG. 2 is a diagram to explain a halotrisilane preparation method according to some embodiments;

FIG. 3 is a diagram to explain a halotrisilane preparation method according to some embodiments;

FIG. 4 is a diagram to explain a halotrisilane preparation method according to embodiments;

FIGS. 5A to 5C each show a Gas Chromatography (GC) analysis result of a primary product acquired according to a halotrisilane preparation method according to embodiments;

FIG. 5D shows a GC analysis result of a secondary product acquired according to a halotrisilane preparation method according to embodiments;

FIGS. 6 and 7 show some processes for explaining a method of manufacturing a semiconductor device according to embodiments;

FIGS. 8 to 10 show some processes for explaining a method of manufacturing a semiconductor device according to embodiments; and

FIGS. 11A, 11B, 12, 13, and 14 show some processes for explaining a method of manufacturing a semiconductor device according to embodiments.

### DETAILED DESCRIPTION OF THE EMBODIMENTS

Hereinafter, one or more embodiments of inventive concepts will be described in detail with reference to the attached drawings. Like reference numerals in the drawings denote like elements, and repeated descriptions thereof will be omitted.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

In the present specification, a horizontal direction may include a first horizontal direction (an X direction) and a second horizontal direction (a Y direction) which cross each other. A direction crossing the first horizontal direction (the X direction) and the second horizontal direction (the Y direction) may be referred to as a vertical direction (a Z direction). In the present specification, the vertical level may be referred to as a height level of any structure along the vertical direction (the Z direction).

In the present specification, although the terms “first” and “second” are used to describe various devices or components, such devices or components must not be limited to the above terms. These terms are used only to distinguish one device or component from another. Therefore, the first device or component stated hereinafter may denote the second device or component in the spirit of inventive concepts.

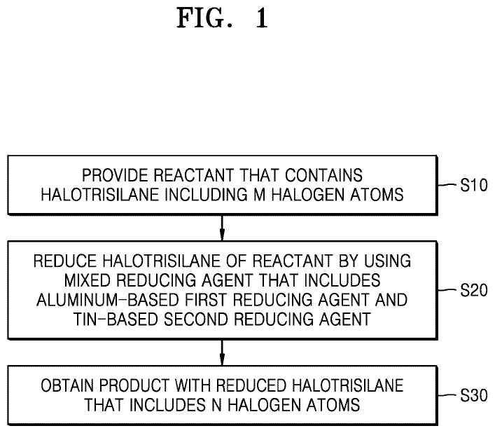

FIG. 1 is a diagram to explain a halotrisilane preparation method according to some embodiments.

Referring to FIG. 1, the halotrisilane preparation method according to some embodiments includes operation S10 of providing a reactant that contains halotrisilane including M halogen atoms (where, M is a natural number from 2 to 8), operation S20 of reducing the halotrisilane in the reactant by using a mixed reducing agent that includes an aluminum-based first reducing agent and a tin-based second reducing agent, and operation S30 of obtaining a product that includes the reduced halotrisilane with N halogen atoms (where, N is a natural number from 1 to 7 and N<M).

The reactant may include at least one of dihalotrisilane, trihalotrisilane, tetrahalotrisilane, pentahalotrisilane, hexahalotrisilane, heptahalotrisilane, and octahalotrisilane. For example, the reactant may include octahalotrisilane.

The halogen atom included in the halotrisilane of the reactant may include at least one of fluorine (F), chlorine (Cl), bromine (Br), and iodine (I). For example, the halogen atom may include Cl. For example, the reactant may include octachlorotrisilane (Si₃Cl₈).

The aluminum-based first reducing agent included in the mixed reducing agent may include, for example, aluminum hydride such as lithium aluminum hydride, alkylaluminum hydride, and sodium bis(2-methoxyethoxy) aluminum hydride. The first reducing agent may be used alone or in combination with two or more other types.

In some embodiments, the first reducing agent may include alkylaluminum hydride represented by Formula 1-1 below.

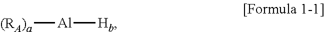

In Formula 1-1, a and b are each either 1 or 2, and a+b=3.

In Formula 1-1 above, R_{A} may include an alkyl group. For example, R_{A} may include an alkyl group having 1 to 10 carbon atoms. The C1 to C10 alkyl group may include, for example, a methyl group, an ethyl group, a propyl group, a butyl group, a pentyl group, a hexyl group, a heptyl group, an octyl group, a nonyl group, a decyl group, or isomers thereof, but one or more embodiments are not limited thereto. In some embodiments, R_{A} may include an isobutyl group.

In some embodiments, in Formula 1-1 above, a may be 2 and b may be 1. For example, the first reducing agent may be represented by Formula 1-2 below.

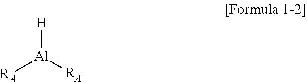

In some embodiments, the first reducing agent may include diisobutylaluminum hydride (DIBAL-H).

The tin-based second reducing agent included in the mixed reducing agent may include, for example, tin hydride such as alkyltin hydride. The tin-based reducing agent may be used alone or in combination with two or more types.

In some embodiments, the second reducing agent may include alkyltin hydride represented by Formula 2-1 below.

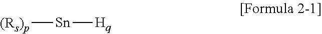

In Formula 2-1, p and q are each a natural number from 1 to 3, and p+q=4.

In Formula 2-1, R_{S} may include an alkyl group or an aryl group. For example, R_{S} may include a C1 to C10 alkyl group, a C6 to C18 aryl group, a C6 to C18 arylalkyl group, or a C6 to C18 alkylaryl group. The C1 to C10 alkyl group may include, for example, a methyl group, an ethyl group, a propyl group, a butyl group, a pentyl group, a hexyl group, a heptyl group, an octyl group, a nonyl group, a decyl group, or isomers thereof, but one or more embodiments are not limited thereto. The C6 to C18 aryl group may include, for example, a phenyl group, a naphthyl group, or the like, but one or more embodiments are not limited thereto. The C6 to C18 arylalkyl group may include, for example, a benzyl group, a phenethyl group, or the like, but one or more embodiments are not limited thereto. The C6 to C18 alkylaryl group may include, for example, a methylphenyl group, an ethylphenyl group, or the like, but one or more embodiments are not limited thereto. In some embodiments, R_{S} may include an n-butyl group or a phenyl group.

In some embodiments, in Formula 2-1 above, p may be 3 and q may be 1. For example, the second reducing agent may be represented by Formula 2-2 below.

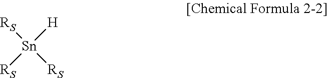

In some embodiments, the second reducing agent may include tri-n-butyltin hydride (nBu₃Sn—H) or triphenyltin hydride (Ph₃Sn—H).

The amount of the mixed reducing agent that may be used to reduce the reactant including halotrisilane may be appropriately adjusted by considering the productivity, cost-effectiveness, and the like. In some embodiments, the mole ratio of the reactant to the mixed reducing agent may be in a range from about 1:0.5 to about 1:5.5. For example, the mole ratio of the reactant to the mixed reducing agent may be in a range from about 1:2.5 to about 1:5.5. For example, the mole ratio of the reactant to the mixed reducing agent may be about 1:2.5, 1:4, or 1:4.5.

In the mixed reducing agent, the mole ratio of the first reducing agent to the second reducing agent may be in a range from about 9.5:0.5 to about 0.5:9.5. In some embodiments, the mole ratio of the first reducing agent to the second reducing agent in the mixed reducing agent may be in a range from about 9:1 to about 1:9. In some embodiments, in the mixed reducing agent, the mole ratio of the first reducing agent to the second reducing agent may be in a range from about 9:1 to about 5:5. For example, in the mixed reducing agent, the mole ratio of the first reducing agent to the second reducing agent may be about 9:1.

The product may include at least one of monohalotrisilane, dihalotrisilane, trihalotrisilane, tetrahalotrisilane, pentahalotrisilane, hexahalotrisilane, and heptahalotrisilane.

In some embodiments, the product may include trihalotrisilane. In some embodiments, the product may further include hexahalotrisilane. In some embodiments, the product may include trihalotrisilane in a relatively high proportion. In some embodiments, the product may include hexahalotrisilane in a relatively high proportion. In other words, the product may include compounds (e.g., heptahalotrisilane) in relatively high proportions, except for trihalotrisilane and hexahalotrisilane.

According to a halotrisilane preparation method according to embodiments, a product containing trihalotrisilane and hexahalotrisilane in relatively high proportions may be obtained, and separation of trihalotrisilane and hexahalotrisilane is relatively easy so that the yields of trihalotrisilane and hexahalotrisilane may be relatively high.

In some embodiments, the halotrisilane in the product may have an asymmetric molecular structure because a specific silicon atom is bound to a greater number of halogen atoms than other silicon atoms. In this case, the other silicon atoms may be bound to a relatively smaller number of halogen atoms, or the distribution of halogen atoms may be disproportionate. For example, the product may include 1,1,1-trihalotrisilane. For example, the product may further include 1,1,1,2,2,3-hexahalotrisilane. Compared to halotrisilane with a symmetric molecular structure, halotrisilane having an asymmetric molecular structure has relatively weaker bonds between silicon atoms and thus may be relatively more suitable for the deposition of silicon-containing layers at low temperatures.

The halogen atoms included in the halotrisilane of the product may include at least one of F, Cl, Br, and I. For example, the halogen atom may include Cl. Because the halogen atoms may form acids by combining with hydrogen atoms during the deposition of silicon-containing layers, selectivity may be achieved without supplying acid externally because of the acid etching effect during selective epitaxial growth.

For example, the product may include trihalotrisilane and may include at least one of 1,1,1-trifluorotrisilane, 1,1,1-trichlorotrisilane, 1,1,1-tribromotrisilane, and 1,1,1-triiodotrisilane.

For example, the product may further include hexahalotrisilane and may include at least one of 1,1,1-hexafluorotrisilane, 1,1,1-hexachlorotrisilane, 1,1,1,2,2,3-hexabromotrisilane, and 1,1,1,2,2,3-hexaiodotrisilane.

Halotrisilane with N halogen atoms (where, N is a natural number from 1 to 7 and N<M), which is included in the product, may be obtained from halotrisilane with M halogen atoms in the reactant as some of the M halogen atoms are substituted with hydrogen atoms through a partial reduction reaction using a mixed reducing agent. For example, in octachlorotrisilane included in the reactant, some of the eight halogen atoms are substituted with hydrogen atoms through a partial reduction reaction using a mixed reducing agent, resulting in trihalotrisilane and hexahalotrisilane as products. For example, in octachlorotrisilane included in the reactant, some of the eight halogen atoms may be substituted with hydrogen atoms through a partial reduction reaction using a mixed reducing agent, resulting in trichlorotrisilane and hexachlorotrisilane as products.

In the halotrisilane preparation method according to some embodiments, a separate solvent may not be required, other than the mixed reducing agent used as a reducing agent. When halotrisilane is prepared using only the mixed reducing agent without a separate solvent, halotrisilane may be relatively easily purified compared to other preparation methods using separate solvents, leading to an improved yield and greater suitability for mass production.

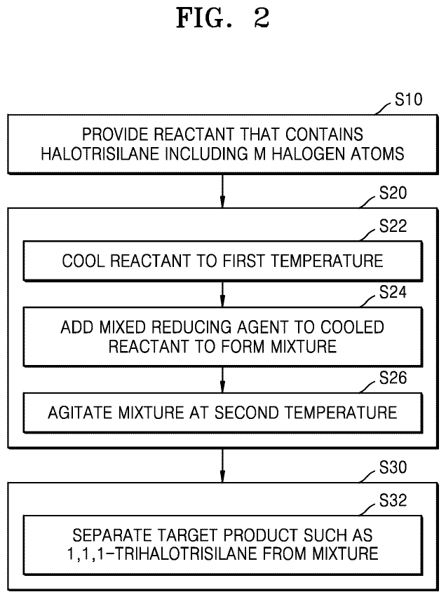

FIGS. 2 to 4 are various example flowcharts to explain a halotrisilane preparation method according to some embodiments. For convenience of explanation, the description already provided in the description of FIG. 1 is briefly summarized or omitted.

Referring to FIG. 2, in the halotrisilane preparation method according to some embodiments, operation S20 of reducing halotrisilane of the reactant by using the mixed reducing agent may include operation S22 of cooling the reactant to a first temperature, operation S24 of adding the mixed reducing agent to the cooled reactant to produce a mixture, and operation S26 of agitating the mixture at a second temperature.

In operation S22 of cooling the reactant, the first temperature may be lower than room temperature (e.g., from about 15° C. to about 25° C.). For example, the first temperature may be in a range from about −25° C. to about 15° C. By cooling the reactant to a temperature lower than room temperature, the reactivity between the mixed reducing agent and the halotrisilane included in the reactant is adjusted in operation S24 of adding the mixed reducing agent to the reactant, and thus, the formation of compounds other than trihalotrisilane, for example, dihalotrisilane and tetrahalotrisilane, may be slightly reduced.

In operation S22 of cooling the reactant, the first temperature may be higher than the freezing point of halotrisilane. In an embodiment, when the reactant includes hexachlorotrisilane, the first temperature may be in a range from about −22° C. to about 15° C. Accordingly, liquid halotrisilane may be provided.

In operation S24 of producing the mixture, the mixed reducing agent may include an aluminum-based first reducing agent and a tin-based second reducing agent. As the mixed reducing agent is added to the reactant and they are mixed, a partial reduction reaction may occur on the reactant. To this end, reduced halotrisilane, for example, 1,1,1-trihalotrisilane, may be formed within the mixture.

In operation S26 of agitating the mixture, the second temperature may be higher than the first temperature. For example, the second temperature may be room temperature. For example, the second temperature may be in a range from about 15° C. to about 30° C. For example, the mixture may be agitated after the temperature is increased to room temperature. As the mixture is agitated at the second temperature that is higher than the first temperature, the partial reduction reaction on the reactant may be completed. The agitation time of the mixture may be, for example, about one hour or more. The agitation time of the mixture may be about 3 hours or more.

In some embodiments, all of operation S22 of cooling the reactant, operation S24 of forming the mixture, and operation S26 of agitating the mixture may be performed at atmospheric pressure. To this end, a halotrisilane preparation method may be excellent in terms of productivity and cost-effectiveness, compared to other methods performed under higher-temperature or higher-pressure conditions.

Referring to FIG. 2, in the halotrisilane preparation method according to some embodiments, operation S30 of obtaining the product may include operation S32 of separating a target product, for example, 1,1,1-trihalotrisilane, from the mixture. Operation S32 of separating a target product, for example, 1,1,1-trihalotrisilane, from the mixture may be performed through fractional distillation. For example, 1,1,1-trihalotrisilane may be separated from the mixture through vacuum fractional distillation performed at about 20 torr (vacuum) and about 65° C. However, it is only an example, and the separation of 1,1,1-trihalotrisilane from the mixture may be performed through various separation processes.

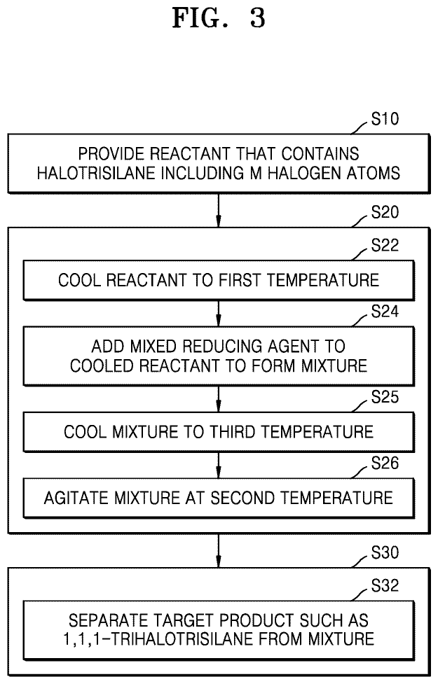

Referring to FIG. 3, in the trihalotrisilane preparation method according to some embodiments, operation S20 of reducing the halotrisilane by using the mixed reducing agent may further include operation S25 of cooling the mixture to a third temperature.

In operation S25 of cooling the mixture, the third temperature may be lower than the first temperature. For example, the third temperature may be in a range from about −30° C. to about 0° C. As the cooled reactant is mixed with the mixed reducing agent, the mixture may be cooled to a temperature that is lower than the freezing point of pure halotrisilane. The third temperature may be adjusted to limit and/or prevent halotrisilane in the mixture from freezing. Accordingly, the mixture in a liquid form may be provided. As the mixture is cooled to a relatively lower temperature, the reactivity in the partial reduction reaction on the reactant may be adjusted so that the formation of compounds other than trihalotrisilane, for example, dihalotrisilane and tetrahalotrisilane, may slightly decrease.

Operation S25 of cooling the mixture may be performed before operation S26 of agitating the mixture at the second temperature. For example, in operation S24 of forming the mixture by mixing halotrisilane with the mixed reducing agent, the temperature of the mixture may be maintained at the third temperature that is lower than the first temperature.

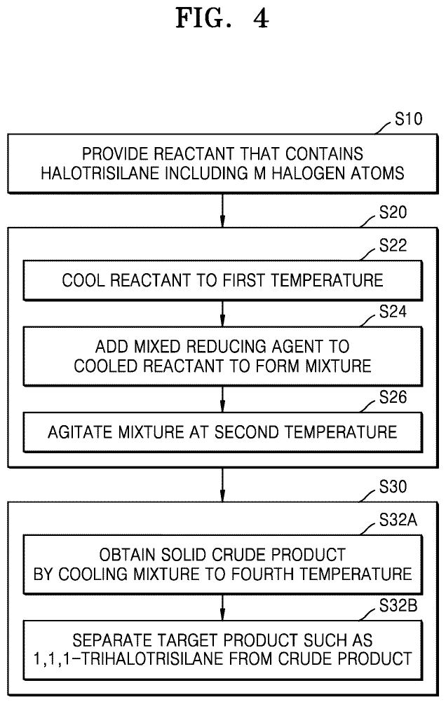

Referring to FIG. 4, in the halotrisilane preparation method according to some embodiments, operation S30 of obtaining the product may include operation S32A of obtaining a solid crude product by cooling the mixture to a fourth temperature and operation S32B of separating a target product, for example, 1,1,1-trihalotrisilane, from the crude product.

In operation S32A of obtaining the crude product, the fourth temperature may be lower than the third temperature. As the mixture is cooled, the solid crude product including 1,1,1-trihalotrisilane may be produced from the mixture.

In operation S32A of obtaining the crude product, the fourth temperature may be higher than the freezing point of the first reducing agent or that of the second reducing agent. In some embodiments, when the first reducing agent includes DIBAL-H, the fourth temperature may be in a range from about −80° C. to about −70° C. For example, the fourth temperature may be about −78° C. To this end, the solid crude product may be selectively separated from the mixture.

Operation S32B of separating the target product, for example, 1,1,1-trihalotrisilane, from the crude product may be performed through, for example, fractional distillation. For example, through vacuum fractional distillation performed at about 20 torr (vacuum) and about 65° C., 1,1,1-trihalotrisilane may be separated from the crude product. However, it is only an example, and the separation of 1,1,1-trihalotrisilane from the crude product (operation S32B) may be performed through different separation processes.

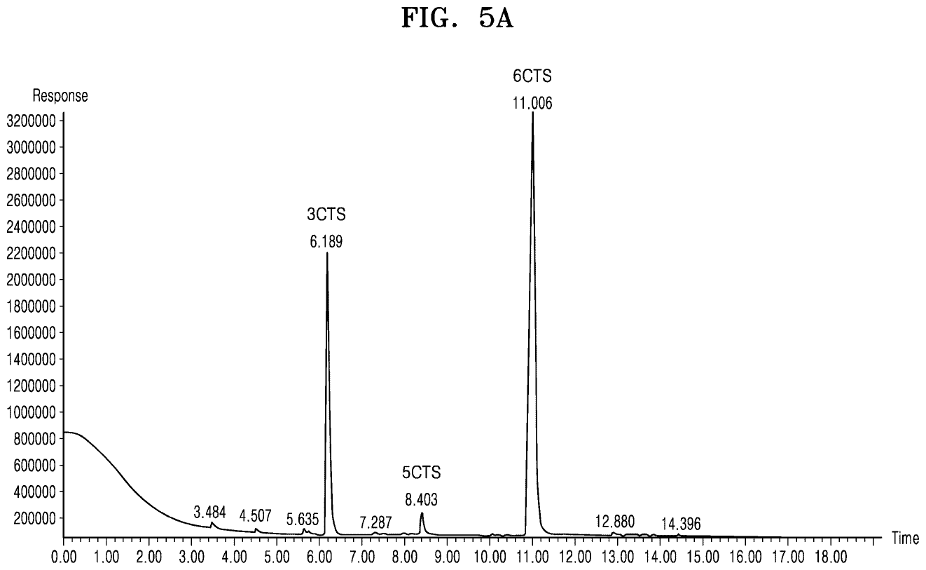

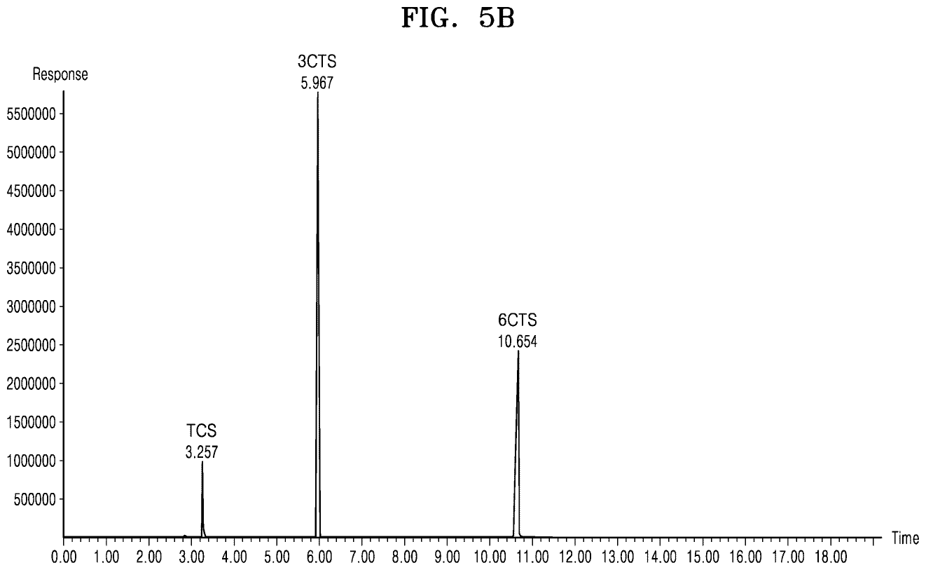

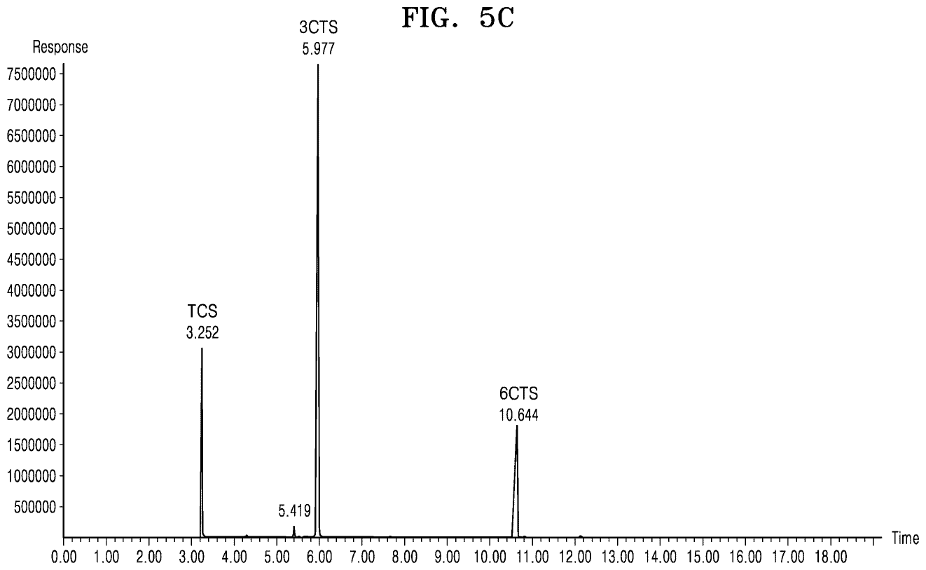

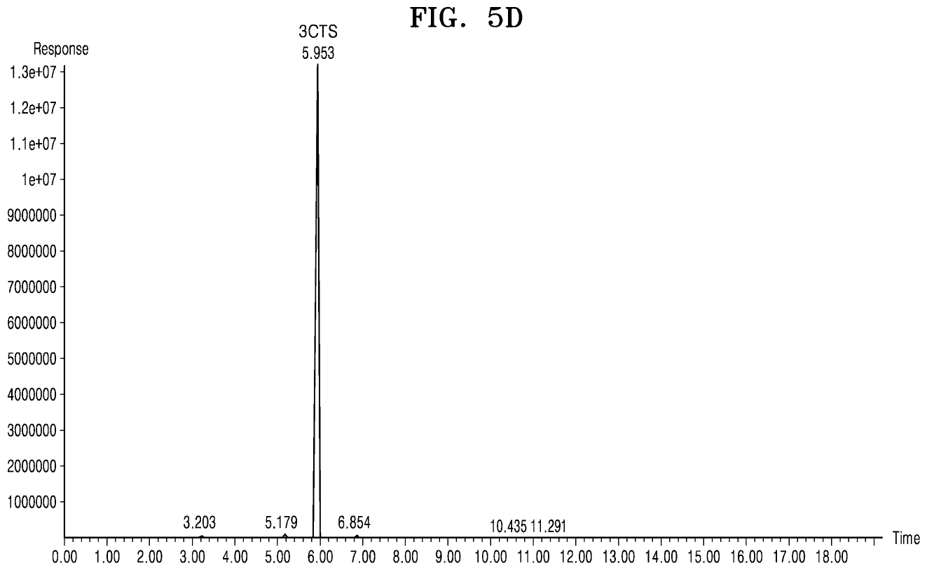

Hereinafter, the halotrisilane preparation method according to embodiments is described in more detail with reference to embodiments below and FIGS. 5A to 5D, respectively. However, inventive concepts are not limited to the examples in FIGS. 5A to 5D.

FIGS. 5A to 5C each show a Gas Chromatography (GC) analysis result of a primary product acquired according to a halotrisilane preparation method according to embodiments.

FIG. 5D shows a GC analysis result of a secondary product acquired according to a halotrisilane preparation method according to embodiments.

### Embodiment 1

In Embodiment 1, the mole ratio of a reactant (octachlorotrisilane (OCTS)) to a mixed reducing agent is about 1:2.5. DIBAL-H and nBu₃Sn—H were used as the mixed reducing agent. In the mixed reducing agent, the mole ratio of DIBAL-H to nBu₃Sn—H is about 9:1.

After removing air from a dried reactor by using nitrogen, 50 g of OCTS (136 mmol) was injected into the reactor through nitrogen pressurization, and the temperature of the reactor was cooled to 0° C. by using a cooling bath. A mixed reducing agent containing 49.49 g (306 mmol) of DIBAL-H and 9.89 g (34 mmol) of nBu₃Sn—H was slowly added to the reactor by using a dropping funnel and then agitated, and the temperature of the reactor was gradually further cooled to −10° C. while carefully limiting and/or preventing octachlorotrisilane from freezing. After the mixed reducing agent was fully added thereto, the cooling bath was removed, and the temperature of the reactor was increased to room temperature to additionally agitate the mixed reducing agent for three hours.

After the reaction was completed, a container cooled to −78° C. was used as a receiving vessel, and a reaction mixture was fractionally distilled at 65° C. and 20 torr (vacuum) so that a primary product (a crude product) containing 1,1,1-trichlorotrisilane (3CTS) was obtained. The GC analysis result showed that the primary product contained 28.55% of 3CTS and 56% of 1,1,1,2,2,3-hexachlorotrisilane (6CTS). In addition, the primary product contained a trace amount of 1,1,1,2,2-heptachlorotrisilane (5CTS). Based on the amount of the mixed reducing agent used, the yield of 3CTS was about 36%, and that of 6CTS was about 56%.

For GC analysis, an Agilent 7890B TCD was used, and in this case, an SPB®-1 Capillary GC Column was utilized for measurement. (Sample injection temperature: 175° C., flow rate: 1 ml/min, and column temperature: 275° C.)

### Embodiment 2

In Embodiment 2, the mole ratio of a reactant (OCTS) to the mixed reducing agent was 1:4. DIBAL-H and nBu₃Sn—H were used as the mixed reducing agent. In the mixed reducing agent, the mole ratio of DIBAL-H to nBu₃Sn—H is about 9:1.

Except for the use of 300 g (816 mmol) of OCTS, 417.54 g (2,936 mmol) of DIBAL-H, and 94.95 g (326 mmol) of nBu₃Sn—H, a primary product containing 3CTS was obtained in the same way as in Embodiment 1.

According to Embodiment 2, 156.1 g of the primary product including 3CTS was obtained. According to the GC analysis result, the primary product contained 57.8% of 3CTS and 36.6% of 6CTS. In addition, the primary product contained a trace amount of trichlorosilane (TCS). Based on the amount of the mixed reducing agent used, the yield of 3CTS was about 71%, and that of 6CTS was about 29%.

### Embodiment 3

In Embodiment 3, the mole ratio of OCTS to the mixed reducing agent is about 1:4.5. DIBAL-H and nBu₃Sn—H were used as the mixed reducing agent. In the mixed reducing agent, the mole ratio of DIBAL-H to nBu₃Sn—H is about 9:1.

Except for the use of 50 g (136 mmol) of OCTS, 72.29 g (550 mmol) of DIBAL-H, and 17.80 g (61 mmol) of nBu₃Sn—H, a primary product containing 3CTS was obtained in the same way as in Embodiment 1.

According to Embodiment 3, 23.07 g of the primary product including 3CTS was obtained. According to the GC analysis result, the primary product contained 66.6% of 3CTS and 19.47% of 6CTS. In addition, the primary product contained a trace amount of TCS. Based on the amount of the mixed reducing agent used, the yield of 3CTS was about 64%, and that of 6CTS was about 12%.

The results of Embodiment 1 to Embodiment 3 described above are shown in Table 1 below.

TABLE 1

| | Mole ratio of | Ratio | Ratio | Yield | Yield |
|---|---|---|---|---|---|
| | reactant to | including | including | of | of |
| | mixed reducing | 3CTS | 6CTS | 3CTS | 6CTS |
| | agent | (%) | (%) | (%) | (%) |
| Embodiment 1 | 1:2.5 | 28.55 | 67.06 | 36 | 56 |
| Embodiment 2 | 1:4 | 57.80 | 36.60 | 71 | 29 |
| Embodiment 3 | 1:4.5 | 66.60 | 19.47 | 64 | 12 |

Referring to Table 1, it was identified that as the mole ratio of the mixed reducing agent increases, the ratio of 3CTS increases relative to that of 6CTS. In addition, in Embodiment 2 where the mole ratio of the reactant to the mixed reducing agent is 1:4, the yield of 3CTS was 71%, which was the highest.

### Embodiment 4

977 g of the primary product was purified through vacuum fractional distillation at about 50 torr and about 54° C. by using a 15 cm column filled with a Pro-Pak, thus obtaining 437 g of a secondary product. According to the GC analysis, the primary product contained about 55.6% of 3CTS, while the secondary product contained about 99.34% of 3CTS. As shown in Embodiment 4, during vacuum fractional distillation, a secondary product including highly pure 3CTS may be obtained. The GC analysis was conducted under the same conditions as those in Embodiment 1.

As demonstrated in Embodiment 1 to Embodiment 4, as the mixed reducing agent was used according to the halotrisilane preparation method according to some embodiments, the target product (1,1,1-trihalotrisilane) may be obtained with a relatively high yield.

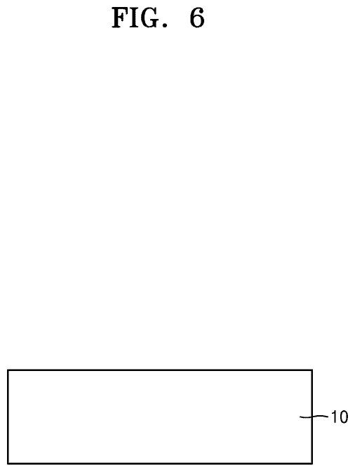

Hereinafter, with reference to FIGS. 6 to 14, a method of manufacturing a semiconductor device by using the above-described halotrisilane preparation method is described.

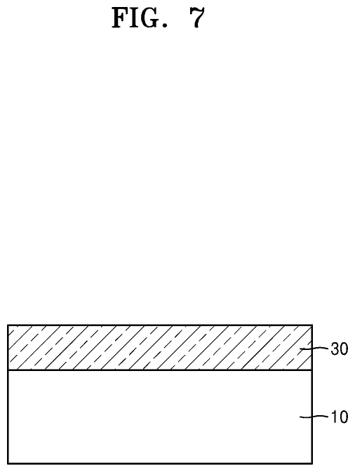

FIGS. 6 and 7 are diagrams showing some processes for explaining a method of manufacturing a semiconductor device according to embodiments.

Referring to FIG. 6, a first substrate 10 may be provided. The first substrate 10 may be bulk silicon or a silicon-on-insulator (SOI). The first substrate 10 may be a silicon substrate and may include another material, for example, silicon germanium (SiGe), gallium arsenide (GaAs), a silicon germanium on insulator (SGOI), indium antimonide (InSb), lead telluride compounds, indium arsenide (InAs), indium phosphide (InP), or gallium antimonide (GaSb). Alternatively, the first substrate 10 may include an epitaxial layer formed on a base substrate or may be a ceramic substrate, a quartz substrate, or a glass substrate for displays.

Referring to FIG. 7, a silicon-containing layer 30 may be formed on the first substrate 10. The silicon-containing layer 30 may include, for example, Si or a silicon compound such as SiGe, silicon antimonide (SiSb), silicon phosphide (SiP), or silicon arsenide (SiAs). In some embodiments, the silicon-containing layer 30 may include Si or Si compounds doped with impurities. The silicon-containing layer 30 may be formed from a silicon precursor. For example, a deposition process of forming the silicon-containing layer 30 using the silicon precursor may be performed. The deposition process may include, for example, at least one of Chemical Vapor Deposition (CVD), Atomic Layer Deposition (ALD), Plasma Enhanced CVD (PECVD), and Plasma Enhanced ALD (PEALD), but is not limited thereto.

The silicon precursor may be provided according to the halotrisilane preparation method according to the one or more embodiments above. For example, providing the silicon precursor may include providing a reactant that contains halotrisilane with M halogen atoms (where, M is a natural number from 2 to 8) (operation S10 of FIG. 1) and reducing the reactant by using a mixed reducing agent that includes an aluminum-based first reducing agent and a tin-based second reducing agent (operation S20 of FIG. 1).

To this end, the silicon precursor that includes the reduced halotrisilane including N halogen atoms (where, N is a natural number from 1 to 7 and N<M) may be provided. In some embodiments, the silicon precursor may include 1,1,1-trihalotrisilane. In some embodiments, the silicon precursor may include 1,1,1-trihalotrisilane and 1,1,1,2,2,3-hexahalotrisilane.

In some embodiments, the silicon-containing layer 30 may include an epitaxial layer grown from the first substrate 10. In some embodiments, the silicon-containing layer 30 may be used as a channel of a semiconductor device. For example, the silicon-containing layer 30 may be used as a channel of a volatile memory device such as Dynamic Random Access Memory (DRAM) or a channel of a non-volatile memory device such as NAND flash, but is not limited thereto.

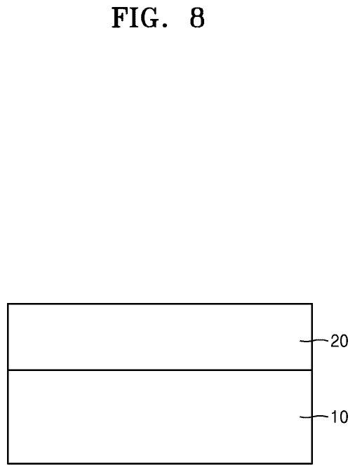

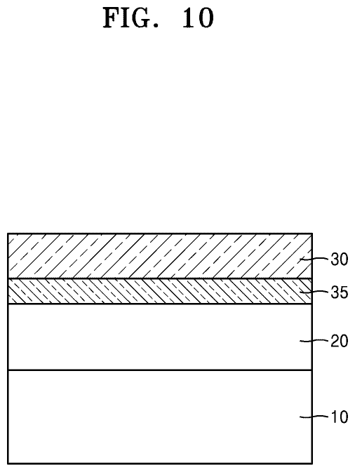

FIGS. 8 and 10 show some processes for explaining a method of manufacturing a semiconductor device according to embodiments.

Referring to FIG. 8, a lower layer 20 may be formed on the first substrate 10. The lower layer 20 may include, for example, an insulating material such as silicon oxide (SiO₂), silicon nitride (SiN), or silicon oxynitride (SiON). However, it is only an example, and the lower layer 20 may include a conductive material such as metal, metal nitride, metal silicide, or a metal silicide nitride layer and may also include a semiconductor material such as polysilicon.

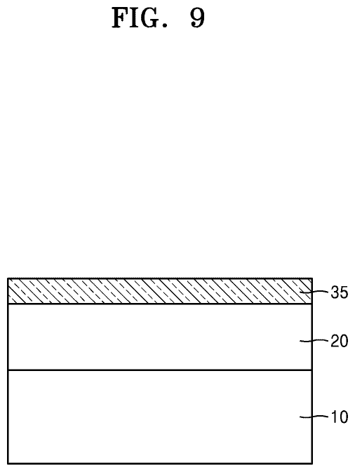

Referring to FIG. 9, a seed layer 35 may be formed on the lower layer 20. For example, a deposition process of forming the seed layer 35 using the silicon precursor may be performed. The silicon precursor may be provided according to the halotrisilane preparation method according to the embodiments above, and detailed descriptions thereof are omitted.

Referring to FIG. 10, the silicon-containing layer 30 is formed on the seed layer 35. The seed layer 35 may function as a seed for forming the silicon-containing layer 30 on the lower layer 20. The silicon-containing layer 30 may include an epitaxial layer grown from the seed layer 35.

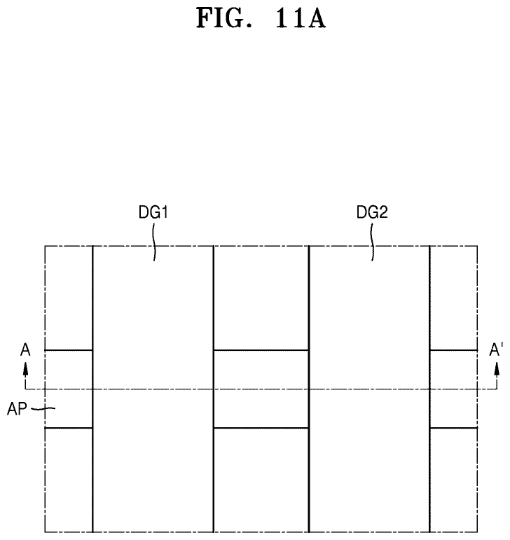

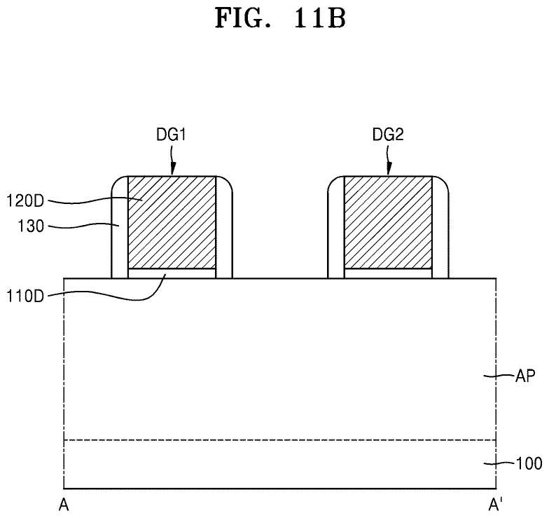

FIGS. 11A, 11B, 12, 13, and 14 show some processes for explaining a method of manufacturing a semiconductor device according to embodiments.

FIG. 11B is a cross-sectional view of the semiconductor device of FIG. 11A, taken along a line A-A′.

Referring to FIGS. 11A and 11B, an active pattern AP, a first dummy gate structure DG1, and a second dummy gate structure DG2 may be formed on a second substrate 100.

The second substrate 100 may be bulk silicon or a silicon-on-insulator (SOI) substrate. The second substrate 100 may be a silicon substrate or may include another material, for example, SiGe, GaAs, a silicon germanium on insulator (SGOI), InSb, lead telluride compounds, InAs, InP, or GaSb. Alternatively, the second substrate 100 may include an epitaxial layer formed on a base substrate or may be a ceramic substrate, a quartz substrate, or a glass substrate for displays.

The active pattern AP may be formed on the second substrate 100. The active pattern AP may extend in a first direction X. The active pattern AP may be a portion of the second substrate 100 and may include an epitaxial layer grown from the second substrate 100. The active pattern AP may include, for example, an elemental semiconductor material such as Si or Ge. In addition, the active pattern AP may include one or more compound semiconductors, for example, group IV-IV compound semiconductors or group III-V compound semiconductors. In the description below, it is described that the active pattern AP is a silicon pin-shaped pattern including Si.

The first dummy gate structure DG1 and the second dummy gate structure DG2 may be formed on the second substrate 100 and the active pattern AP. Each of the first dummy gate structure DG1 and the second dummy gate structure DG2 may extend in a second direction Y crossing the first direction X. Each of the first dummy gate structure DG1 and the second dummy gate structure DG2 may include a dummy gate dielectric layer 110D, a dummy gate electrode 120D, and a gate spacer 130.

The dummy gate dielectric layer 110D and the dummy gate electrode 120D may be sequentially stacked on the second substrate 100 and the active pattern AP. For example, an insulating layer and a conductive layer may be sequentially formed on the second substrate 100 and the active pattern AP. Next, a process of patterning the insulating layer and the conductive layer may be performed. Accordingly, the dummy gate dielectric layer 110D and the dummy gate electrode 120D extending in the second direction Y may be formed.

The gate spacer 130 may extend along the side surfaces of the dummy gate dielectric layer 110D and the dummy gate electrode 120D. The gate spacer 130 may include an insulating material, for example, at least one of SIN, SiON, SiO₂, SiOCN, and a combination thereof, but is not limited thereto.

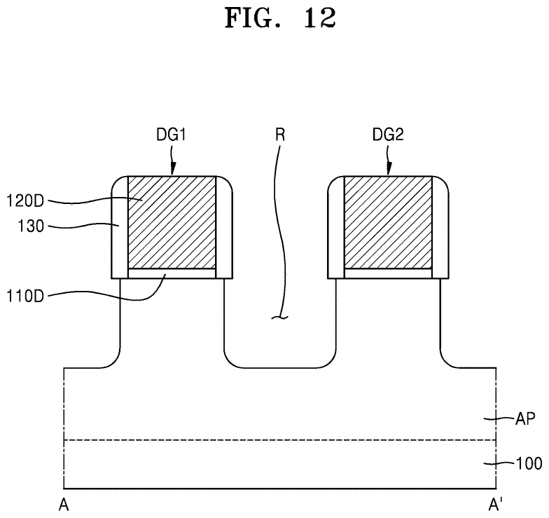

Referring to FIG. 12, in the results of FIGS. 11A and 11B, a recess R extending into the active pattern AP may be formed.

The recess R may be formed through an etching process in which the first dummy gate structure DG1 and the second dummy gate structure DG2 are used as etch masks. The etching process may include, for example, a Reactive Ion Etching (RIE) process or a wet etching process, but one or more embodiments are not limited thereto. Accordingly, the recess R, which is adjacent to the side surfaces of the first dummy gate structure DG1 and the second dummy gate structure DG2, may be formed in the active pattern AP. In some embodiments, the recess R may include an undercut structure formed on a lower portion of the gate spacer 130.

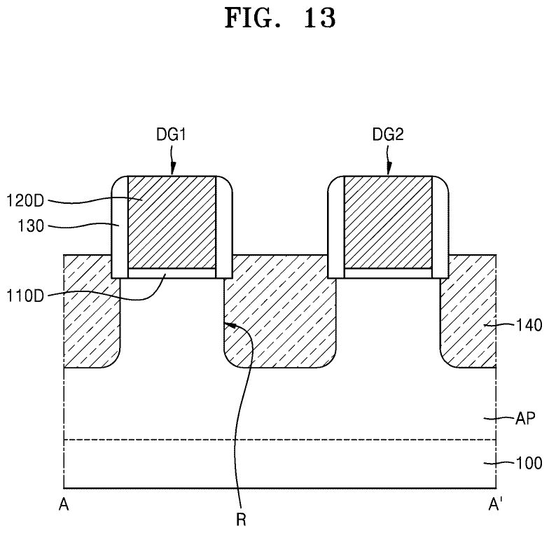

Referring to FIG. 13, in the result of FIG. 12, a source/drain area 140 may be formed in the recess R.

The source/drain area 140 may include Si or Si compounds such as SiGe, SiSb, SiP, or SiAs. In some embodiments, the source/drain area 140 may include Si or Si compounds doped with impurities.

The source/drain area 140 may be formed from the silicon precursor. For example, an epitaxial growth process of forming the source/drain area 140 by using the silicon precursor may be performed. In some embodiments, the source/drain area 140 may be formed through an epitaxial growth process and an in-situ doping process. The silicon precursor may be provided according to the halotrisilane preparation method according to the embodiments above, and detailed descriptions thereof are omitted.

In some embodiments, the source/drain area 140 may be an elevated source/drain area. That is, the uppermost portion of the source/drain area 140 may extend above the uppermost surface of the active pattern AP.

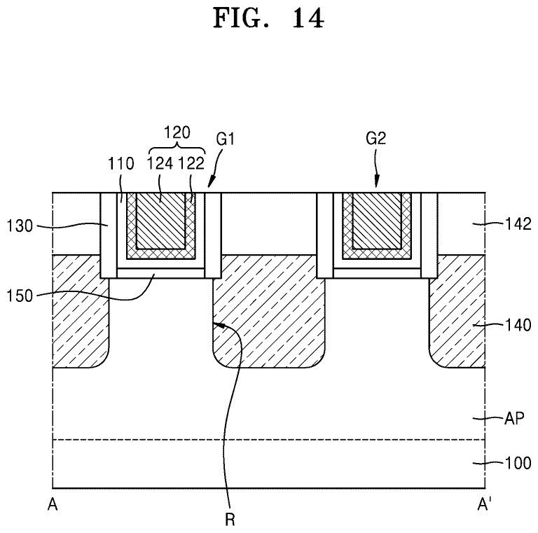

Referring to FIG. 14, a first gate structure G1 and a second gate structure G2 may be formed on the result of FIG. 13.

The first gate structure G1 and a second gate structure G2 may be formed through a replacement process. For example, an interlayer insulating layer 142 covering the second substrate 100, the active pattern AP, the source/drain area 140, the first dummy gate structure DG1, and the second dummy gate structure DG2 may be formed. Then, the dummy gate dielectric layer 110D and the dummy gate electrode 120D may be removed. Next, a gate dielectric layer 110 and a gate electrode 120 may be formed in a region where the dummy gate dielectric layer 110D and the dummy gate electrode 120D are removed. To this end, the first gate structure G1 and the second gate structure G2 including the gate dielectric layer 110, the gate electrode 120, and the gate spacer 130 may be formed.

In some embodiments, an interface layer (not shown) may be formed before the gate dielectric layer 110 is formed. Accordingly, the interface layer may be between the active pattern AP and the gate dielectric layer 110. The interface layer may include, for example, SiO₂, but one or more embodiments are not limited thereto. In some embodiments, the interface layer may be omitted.

The gate dielectric layer 110 may include a dielectric material, for example, at least one of SiO₂, SION, SiN, a high-k material with a greater dielectric constant than SiO₂, and a combination thereof, but one or more embodiments are not limited thereto. The high-k material may include, for example, at least one of hafnium oxide (HfO₂), hafnium silicon oxide (HfSiO), hafnium aluminum oxide (HfAlO), lanthanum oxide (La₂O₃), lanthanum aluminum oxide (LaAlO₃), zirconium oxide (ZrO₂), zirconium silicon oxide (ZrSiO), tantalum oxide (Ta₂O₅), titanium oxide (TiO₂), barium strontium titanate (BST), barium titanate (BTO), strontium titanate (STO), yttrium oxide (Y₂O₃), aluminum oxide (Al₂O₃), lead scandium tantalum oxide (PST), lead zinc niobate (PZN), and a combination thereof, but is not limited thereto.

The gate electrode 120 may include a conductive material, for example, at least one of titanium nitride (TiN), tungsten nitride (WN), tantalum nitride (TaN), ruthenium (Ru), titanium carbide (TiC), tantalum carbide (TaC), Ti, silver (Ag), Al, TiAl, titanium aluminum nitride (TiAlN), titanium aluminum carbide (TiAlC), tantalum carbonitride (TaCN), tantalum silicon nitride (TaSiN), manganese (Mn), Zr, W, Al, and a combination thereof, but one or more embodiments are not limited thereto.

In some embodiments, the gate electrode 120 may include a work function adjusting layer 122 that adjusts the work function and a filling conductive layer 124 that fills the space left after the work function adjusting layer 122 is formed. The work function adjusting layer 122 may include, for example, at least one of TiN, TaN, TiC, TaC, TiAlC, and a combination thereof, but is not limited thereto. The filling conductive layer 124 may include, for example, W or Al, but is not limited thereto.

As a semiconductor device according to some embodiments, a Fin Field Effect Transistor (FinFET) including a fin-patterned channel area is only described, but it is only an example. As another example, the semiconductor device may include an MBCFET® with a multi-bridge channel, a tunneling FET, vertical FET (VFET), or Complementary FET (CFET). Alternatively, the semiconductor device may include a bipolar junction transistor, a Laterally Diffused Metal-Oxide Semiconductor (LDMOS), or the like.

While inventive concepts have been particularly shown and described with reference to embodiments thereof, it will be understood that various changes in form and details may be made therein without departing from the spirit and scope of the following claims.

What is claimed is:

1. A halotrisilane preparation method comprising:
providing a reactant that contains halotrisilane comprising M halogen atoms, where M is a natural number from 2 to 8;
reducing the halotrisilane in the reactant using a mixed reducing agent to form a reduced halotrisilane, the mixed reducing agent including a first reducing agent represented by Formula 1-1 and a second reducing agent represented by Formula 2-1; and
obtaining a product including the reduced halotrisilane, the reduced halotrisilane including N halogen atoms, where N is a natural number from 1 to 7 and where N<M, 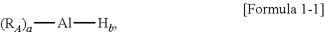
in Formula 1-1 above, R_{A} represents an alkyl group, a and b are each either 1 or 2, and a+b=3. 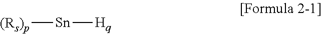
in Formula 2-1 above, R_{S} represents an alkyl group or an aryl group, p and q are each independently a natural number from 1 to 3, and p+q=4.

2. The halotrisilane preparation method of claim 1, wherein, in Formula 1-1, a is 2 and b is 1.

3. The halotrisilane preparation method of claim 1, wherein the first reducing agent comprises diisobutylaluminum hydride (DIBAL-H).

4. The halotrisilane preparation method of claim 1, wherein, in Formula 2-1, p is 3 and q is 1.

5. The halotrisilane preparation method of claim 1, wherein the second reducing agent comprises tri-n-butyltin hydride or triphenyltin hydride.

6. The halotrisilane preparation method of claim 1, wherein the product comprises 1,1,1-trihalotrisilane.

7. The halotrisilane preparation method of claim 1, wherein the product comprises 1,1,1,2,2,3-hexahalotrisilane.

8. The halotrisilane preparation method of claim 1, wherein a mole ratio of the first reducing agent to the second reducing agent is from 9:1 to 1:9.

9. The halotrisilane preparation method of claim 1, wherein a mole ratio of the first reducing agent to the second reducing agent is from 9:1 to 5:5.

10. The halotrisilane preparation method of claim 1, wherein the reactant comprises octahalotrisilane.

11. A halotrisilane preparation method comprising:
providing a reactant that contains halotrisilane comprising M halogen atoms, where M is a natural number from 2 to 8;
cooling the reactant to a first temperature that is higher than a freezing point of the reactant and lower than room temperature, the cooling the reactant providing a cooled reactant;
forming a mixture by adding a mixed reducing agent to the cooled reactant, the mixed reducing agent including an aluminum-based first reducing agent and a tin-based second reducing agent;
agitating the mixture at a second temperature, the second temperature being higher than the first temperature; and
separating, from the mixture, a product including halotrisilane comprising N halogen atoms, where N is a natural number from 1 to 7 and where N<M.

12. The halotrisilane preparation method of claim 11, wherein
the aluminum-based first reducing agent is represented by Formula 1-1 below, and
the tin-based second reducing agent is represented by Formula 2-1 below, 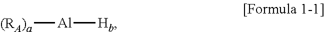
in Formula 1-1 above, R_{A} represents an alkyl group, a and b are each either 1 or 2, and a+b=3, 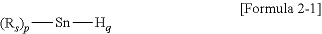
in Formula 2-1 above, R_{S} represents an alkyl group or an aryl group, p and q are each a natural number from 1 to 3, and p+q=4.

13. The halotrisilane preparation method of claim 12, wherein,
in Formula 1-1, a is 2 and b is 1, and
in Formula 2-1, p is 3 and q is 1.

14. The halotrisilane preparation method of claim 11, wherein
the aluminum-based first reducing agent comprises diisobutylaluminum hydride (DIBAL-H), and
the tin-based second reducing agent comprises tri-n-butyltin hydride or triphenyltin hydride.

15. The halotrisilane preparation method of claim 11, wherein a mole ratio of the aluminum-based first reducing agent to the tin-based second reducing agent is 9:1.

16. The halotrisilane preparation method of claim 11, wherein the first temperature is in a range from −25° C. to 15° C.

17. The halotrisilane preparation method of claim 11, wherein the second temperature is in a range from 15° C. to 30° C.

18. A method of manufacturing a semiconductor device, the method comprising:
providing a substrate;
providing a silicon precursor on the substrate; and
forming a silicon-containing layer using the silicon precursor on the substrate, wherein
the silicon precursor comprises halotrisilane with at least one halogen atom,
the providing the silicon precursor comprises providing octahalotrisilane and reducing the octahalotrisilane using a mixed reducing agent, and
the mixed reducing agent comprises an aluminum-based first reducing agent and a tin-based second reducing agent.

19. The method of claim 18, wherein
the aluminum-based first reducing agent is represented by Formula 1-1 below,
the tin-based second reducing agent is represented by Formula 2-1 below, 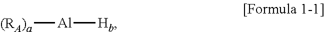
in Formula 1-1 above, R_{A} represents an alkyl group, a and b are each either 1 or 2, and a+b=3, 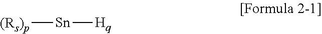
in Formula 2-1 above, R_{S} represents an alkyl group or an aryl group, p and q are each a natural number from 1 to 3, and p+q=4.

20. The method of claim 19, wherein
R_{A} comprises a butyl group,
R_{S} comprises a butyl group or a phenyl group, and
a mole ratio of the aluminum-based first reducing agent to the tin-based second reducing agent is 9:1.
